(19) United States
(12) Patent Application Publication
(10) Pub. No.: US 2024/0292510 A1
(43) Pub. Date: Aug. 29, 2024

(54) APPARATUS AND METHOD FOR PRODUCING DROPLETS OF TARGET MATERIAL IN AN EUV SOURCE

(71) Applicant: ASML Netherlands B.V., Veldhoven (NL)

(72) Inventors: Alexander Igorevich Ershov, Escondido, CA (US); Theodorus Wilhelmus Driessen, Asten-Heusden (NL); Dietmar Uwe Herbert Trees, San Diego, CA (US); Vikas Giridhar Telkar, Escondido, CA (US)

(21) Appl. No.: 18/571,490

(22) PCT Filed: Jun. 2, 2022
(86) PCT No.: PCT/EP2022/064988

§ 371 Date: Dec. 18, 2023

Related U.S. Application Data
(60) Provisional application No. 63/214,903, filed on Jun. 25, 2021.

(51) Int. Cl. H05G 2/00

(52) U.S. Cl. CPC H05G 2/006; H05G 2/008

(57) ABSTRACT

Apparatus for and method of accelerating droplets used to generate EUV radiation that comprise an arrangement producing a laser beam directed to an irradiation region and a droplet source. The droplet source includes a fluid exiting a nozzle (200) in a stream that breaks up into droplets that then undergo coalescence. A gas provided for the purpose of accelerating the droplets is caused to flow past the nozzle in a streamwise direction.

### CROSS REFERENCE TO RELATED APPLICATIONS

This application claims priority to U.S. Application No. 63/214,903, filed Jun. 25, 2021, titled APPARATUS FOR AND METHOD PRODUCING DROPLETS OF TARGET MATERIAL IN AN EUV SOURCE, which is incorporated herein in its entirety by reference.

### FIELD

The present application relates to extreme ultraviolet (“EUV”) light sources and their methods of operation. These light sources generate EUV light by creating plasma from a source or target material. In one application, the EUV light may be collected and used in a photolithography process to produce semiconductor integrated circuits.

### BACKGROUND

A patterned beam of EUV light can be used to expose a resist coated substrate, such as a silicon wafer, to produce extremely small features in or on the substrate. Extreme ultraviolet light (also sometimes referred to as soft x-rays) is generally defined as electromagnetic radiation having wavelengths in the range of about 5-100 nm. One particular wavelength of interest for photolithography occurs at 13.5 nm.

Methods to produce EUV light include, but are not necessarily limited to, converting a source material into a plasma state that has a chemical element with an emission line in the EUV range. These elements can include, but are not necessarily limited to, xenon, lithium, and tin.

In one such method, often termed laser produced plasma (“LPP”), the desired plasma can be produced by irradiating a source material, for example, in the form of a droplet, stream or wire, with a laser beam. In another method, often termed discharge produced plasma (“DPP”), the required plasma can be generated by positioning source material having an appropriate emission line between a pair of electrodes and causing an electrical discharge to occur between the electrodes.

One technique for generating droplets involves melting a target or source material such as tin and then forcing the liquid tin under high pressure through a relatively small diameter orifice, such as an orifice having a diameter of about 0.5 μm to about 30 μm, to produce a stream of droplets. Under most conditions, in a process called Rayleigh breakup, naturally occurring instabilities, e.g., noise, in the stream exiting the orifice, will cause the stream to break up into microdroplets. These droplets may have varying velocities and may combine with each other as they travel in the stream to coalesce into larger droplets.

The task of the droplet generator is to place droplets in the primary focus of a collector mirror where they will be used for EUV production. The droplets must arrive at primary focus within certain spatial and temporal stability criteria, that is, with position and timing that is repeatable within acceptable margins. They must also arrive at a given frequency and velocity. Furthermore, the droplets must be fully coalesced, meaning that the droplets must be monodisperse (of uniform size) and arrive at the given drive frequency.

An increasing need for high EUV power at high repetition rates drives requirements for higher speed droplets with higher droplet spacing. Acceleration of the droplets generated by a droplet generator has been achieved in the past by increasing the driving gas pressure. There is a limit, however, to how much droplet velocity can be increased by increasing the driving gas pressure. Using such high pressures presents a number of problems, including but not limited to materials performance and stability at these pressures, an increase in droplet coalescence length at higher pressures, safety, regulatory requirements, etc. Also, fluid flow in the orifice could become turbulent at a given fluid velocity and nozzle geometry, causing droplet instability.

Also, generating droplets of EUV target material requires a very small orifice in the nozzle of the droplet generator. This nozzle can be easily clogged by target material byproducts. For example, when tin is used as the target material, SnOx particles can be formed if oxidizing contamination, such as O2 and H2O gases, can reach the tin inside the nozzle orifice upstream of where the tin starts jetting out of the nozzle orifice. Therefore, protecting the target material inside the nozzle from external contaminants is very important.

During the startup of a droplet generator, the drive pressure must be ramped to the operating range. During that ramp up droplets are produced but they have a lower velocity and size than the normal droplets used for EUV generation. These slower and smaller droplets can have a different trajectory than the normal droplets. As a consequence, the slower and smaller droplets may miss structures within the source vessel intended to mitigate contamination in the source, particularly on the collector, by target material such as a tin catch thus creating undesirable contamination.

Gas acceleration of the droplets generated by a droplet generator has been considered as a way to increase droplet velocities without having to increase the driving gas pressure. For example, U.S. Pat. No. 8,598,551, titled “EUV Radiation Source Comprising a Droplet Accelerator and Lithographic Apparatus”, naming Mestrom et al. as inventors, and issued Dec. 3, 2013, which is hereby incorporated by reference in its entirety, discloses an EUV radiation source that includes a droplet accelerator configured to accelerate the droplets using gas.

It is in this context that the need for the invention arises.

### SUMMARY

The following presents a simplified summary of one or more embodiments in order to provide a basic understanding of the embodiments. This summary is not an extensive overview of all contemplated embodiments and is not intended to identify key or critical elements of all embodiments nor delineate the scope of any or all embodiments. Its sole purpose is to present some concepts of one or more embodiments in a simplified form as a prelude to the more detailed description that is presented later.

According to an aspect of an embodiment, there is a disclosed a droplet generator having a nozzle orifice adapted to emit a stream of EUV target material, the stream including droplets of various sizes, velocities, and states of coalescence, with a flow of gas being introduced to flow past the nozzle orifice in the streamwise direction to accelerate the droplets. In accordance with another aspect of an embodiment, a related method is disclosed of accelerating droplets of various sizes, velocities, and states of coalescence by causing a gas to flow past the nozzle orifice in a streamwise direction.

According to one aspect of an embodiment, there is disclosed a droplet generator for generating a stream of extreme ultraviolet (EUV) source material, the droplet generator comprising a nozzle body having a nozzle orifice adapted to emit a stream of liquid EUV source material from a nozzle orifice in a streamwise direction, a gas introduction assembly arranged to introduce a gas upstream of the nozzle orifice to flow past the nozzle orifice in the streamwise direction, and a gas tube extending in the streamwise direction away from the nozzle orifice, the gas tube extending parallel to and substantially surrounding at least a portion of the stream of liquid EUV source material, the gas also flowing within the gas tube in a streamwise direction parallel to the stream of liquid. The gas introduction assembly may comprise a gas inlet tube, a gas manifold in fluid communication with the gas inlet tube, and a gas plenum in fluid communication with the gas manifold, the gas plenum substantially surrounding the nozzle orifice and a portion of the nozzle body adjacent the nozzle orifice The gas plenum may have a generally circular cross section with a diameter tapering in a gas flow direction from an interface with the gas manifold to an interface with the gas tube such that the plenum may have a generally frustoconical shape. A cross sectional area of the gas plenum may gradually decrease in a gas flow direction from an interface with the gas manifold to an interface with the gas tube. The gas plenum may be configured to cause a circularly symmetric flow of gas starting upstream of and then flowing uniformly past the nozzle orifice. The gas plenum may be configured to accelerate a flow of gas starting upstream of and then flowing uniformly past the nozzle orifice.

In any of the above arrangements the gas introduction assembly may include a diffuser positioned between the gas manifold and the gas plenum. The gas tube extending parallel to and substantially surrounding at least a portion of the stream of liquid EUV source material extends at least to the coalescence length. The portion of the gas tube extending parallel to the stream may have a circular cross section. The apparatus may further comprise an adapter mechanically coupled to the nozzle body and an actuator mechanically coupled to the adapter, wherein the adapter and actuator are adapted to adjust an angular position of the nozzle orifice.

In any of the above arrangements the gas may have a low EUV absorption and may comprise hydrogen. A flow rate of the gas at the nozzle orifice may be in a range of about 0.1 slm to about 10 slm. The gas tube may comprise a refractory metal. The gas tube may comprise molybdenum, tungsten, tantalum, rhenium, or an alloy of molybdenum, tungsten, tantalum, or rhenium. An internal surface of the gas tube may comprise a boron nitride coating.

According to another aspect of an embodiment, there is disclosed a method of accelerating droplets of extreme ultraviolet (EUV) source material, the method comprising providing a nozzle orifice adapted to emit a stream of liquid EUV source material in a streamwise direction from a front of the nozzle orifice, providing a gas supply structure, introducing a flow of gas around the nozzle orifice, and emitting a stream of liquid EUV source material from the nozzle orifice, the flow of gas being introduced from a position behind the nozzle orifice with respect to the stream. The gas supply structure may comprise a gas inlet tube, a gas manifold in fluid communication with the gas inlet tube, and a gas plenum in fluid communication with the gas manifold, the gas plenum substantially surrounding the nozzle orifice and a portion of the nozzle body adjacent the nozzle orifice. The gas supply structure may include a diffuser positioned between the gas manifold and the gas plenum. A gas tube may extend parallel to and substantially surrounding at least a portion of the stream of liquid EUV source material at least to the coalescence length. At least a portion of the gas tube extending parallel to the stream may have a circular cross section. The method may further comprise providing an adapter mechanically coupled to the nozzle body and an actuator mechanically coupled to the adapter, wherein the adapter and actuator are adapted to adjust an angular position of the nozzle orifice.

In any of the above methods, the gas may have a low EUV absorption and may comprise hydrogen. The flow rate of the gas at the nozzle orifice may be in a range of about 0.1 slm to about 10 slm. The gas tube may comprise a refractory metal which may comprise molybdenum, tungsten, tantalum, rhenium, or an alloy of molybdenum, tungsten, tantalum, or rhenium. An internal surface of the gas tube may comprise a boron nitride coating.

According to another aspect of an embodiment, there is disclosed a droplet generator for generating a stream of droplets of extreme ultraviolet (EUV) source material, the droplet generator comprising a nozzle adapted to emit liquid EUV source material from a nozzle orifice, at least one inlet adapted to be connected to a source of a gas, and a first structure in fluid communication with the source of gas and defining a gas plenum surrounding the nozzle orifice and extending ahead of and behind the nozzle orifice. The gas plenum may have a generally circular cross section with a diameter tapering in a gas flow direction towards an interface with the gas tube such that the plenum may have a generally frustoconical shape. A cross sectional area of the gas plenum may gradually decrease in a gas flow direction towards an interface with the gas tube. The gas plenum may be configured to cause a circularly symmetric flow of gas starting upstream of and then flowing uniformly past the nozzle orifice. The gas plenum may be configured to accelerate a flow of gas starting upstream of and then flowing uniformly past the nozzle orifice.

According to another aspect of an embodiment, there is disclosed a method of accelerating droplets of extreme ultraviolet (EUV) source material, the method comprising emitting a stream of liquid EUV source material from a nozzle orifice of a droplet generator and causing gas to flow past the nozzle orifice to flow parallel to the stream of EUV source material to entrain and accelerate droplets of EUV source material in the stream of liquid EUV source material.

Further embodiments, features, and advantages of the present invention, as well as the structure and operation of the various embodiments are described in detail below with reference to accompanying drawings.

### BRIEF DESCRIPTION OF THE DRAWINGS

The accompanying drawings, which are incorporated herein and form part of the specification, illustrate the methods and systems of embodiments of the invention by way of example, and not by way of limitation. Together with the detailed description, the drawings further serve to explain the principles of and to enable a person skilled in the relevant art(s) to make and use the methods and systems presented herein. The drawing features are not necessarily to scale. In the drawings, like reference numbers indicate identical or functionally similar elements.

FIG. 1 is a simplified, schematic diagram of an apparatus including an EUV light source having an LPP EUV light radiator.

FIG. 2 is a not-to-scale cross sectional view of a droplet generator illustrating states of coalescence in a droplet stream.

FIG. 3 is a plan view of a droplet generation system with a droplet accelerator according to an aspect of an embodiment.

FIG. 4 is an exploded view of the droplet accelerator shown in FIG. 3.

Further features and advantages of the invention, as well as the structure and operation of various embodiments of the invention, are described in detail below with reference to the accompanying drawings. It is noted that the invention is not limited to the specific embodiments described herein. Such embodiments are presented herein for illustrative purposes only. Additional embodiments will be apparent to persons skilled in the relevant art based on the teachings contained herein.

### DETAILED DESCRIPTION

Various embodiments are now described with reference to the drawings, wherein like reference numerals are used to refer to like elements throughout. In the following description, for purposes of explanation, numerous specific details are set forth in order to promote a thorough understanding of one or more embodiments. It may be evident in some or all instances, however, that any embodiment described below can be practiced without adopting the specific design details described below. In other instances, well-known structures and devices are shown in block diagram form in order to facilitate description of one or more embodiments. The following presents a simplified summary of one or more embodiments in order to provide a basic understanding of the embodiments. This summary is not an extensive overview of all contemplated embodiments and is not intended to identify key or critical elements of all embodiments nor delineate the scope of any or all embodiments.

Before describing such embodiments in more detail, however, it is instructive to present an example environment in which embodiments of the present invention may be implemented. In the description that follows and in the claims the terms “up,” “down,” “top,” “bottom,” “vertical,” “horizontal,” and like terms may be employed. These terms are intended to show relative orientation only and not any orientation with respect to gravity. Also, in some instances, the terms “upstream”, “downstream” and “streamwise” are used in connection with orientation and position with respect to the droplet stream described below. These terms are intended to have their normal and customary meanings of nearer to the source (or nozzle) for upstream, farther from the source (or nozzle) for downstream, and in the direction of the stream for streamwise.

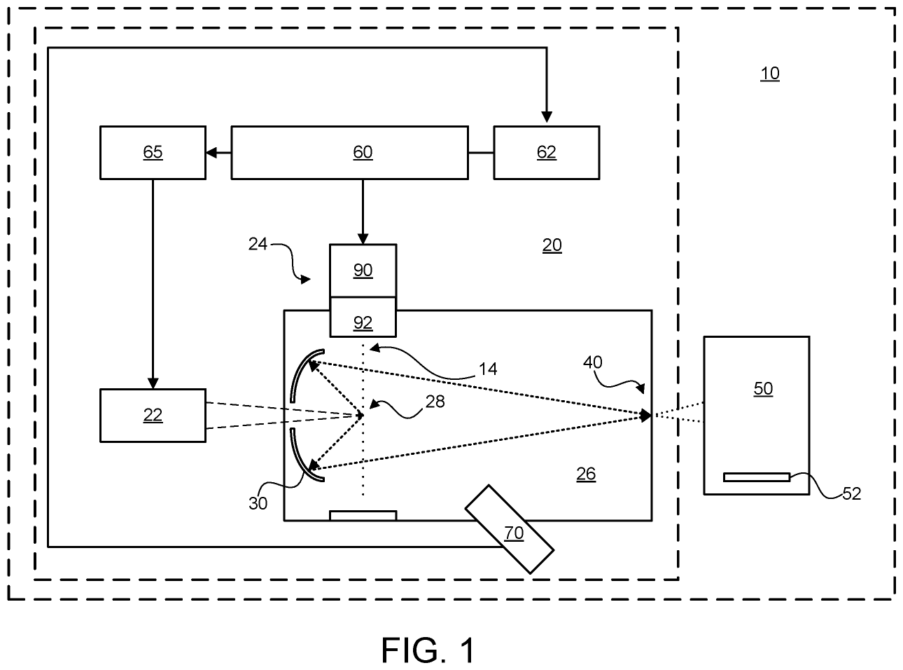

FIG. 1 illustrates a specific example of an apparatus 10 including an EUV light source 20 having an LPP EUV light radiator. As shown, the EUV light source 20 may include a system 22 for generating a train of light pulses and delivering the light pulses into a light source chamber 26. The light pulses may travel along one or more beam paths from the system 22 and into the chamber 26 to illuminate droplets of source material 14 at an irradiation region 28 to produce an EUV light output for exposure of a substrate 52 in an exposure device 50.

Suitable lasers for use in the system 22 shown in FIG. 1 may include a pulsed laser device, e.g., a pulsed gas discharge CO₂ laser device producing radiation at 9.3 μm or 10.6 μm, e.g., with DC or RF excitation, operating at relatively high power, e.g., 10 kW or higher and high pulse repetition rate, e.g., 50 kHz or more. Other lasers producing radiation at other wavelengths, operating at other powers and with different repetition rates may be used in other embodiments. In one particular implementation, the laser may be an axial-flow RF-pumped CO₂ laser having an oscillator-amplifier configuration (e.g., master oscillator/power amplifier (MOPA) or power oscillator/power amplifier (POPA)) with multiple stages of amplification and having a seed pulse that is initiated by a Q-switched oscillator with relatively low energy and high repetition rate, e.g., capable of 100 kHz operation. From the oscillator, the laser pulse may then be amplified, shaped and/or focused before reaching the irradiation region 28. Continuously pumped CO₂ amplifiers may be used for the laser system 22. Alternatively, the laser may be configured as a so-called “self-targeting” laser system in which the droplet serves as one mirror of the optical cavity.

Depending on the application, other types of lasers may also be suitable, e.g., an excimer or molecular fluorine laser operating at high power and high pulse repetition rate. Other suitable examples include a solid state laser, e.g., having a fiber, rod, slab, or disk-shaped active media, other laser architectures having one or more chambers, e.g., an oscillator chamber and one or more amplifying chambers (with the amplifying chambers in parallel or in series), a master oscillator/power oscillator (MOPO) arrangement, a master oscillator/power ring amplifier (MOPRA) arrangement, or a solid state laser that seeds one or more excimer, molecular fluorine or CO₂ amplifier or oscillator chambers. Other designs may be suitable.

In some instances, a source material may first be irradiated by a pre-pulse and thereafter irradiated by a main pulse. Pre-pulse and main pulse seeds may be generated by a single oscillator or two separate oscillators. In some setups, one or more common amplifiers may be used to amplify both the pre-pulse seed and main pulse seed. For other arrangements, separate amplifiers may be used to amplify the pre-pulse and main pulse seeds.

System 22 may include a beam conditioning unit having one or more optics for beam conditioning such as expanding, steering, and/or focusing the beam that reaches the irradiation site 28. For example, a steering system, which may include one or more mirrors, prisms, lenses, etc., may be provided and arranged to steer the laser focal spot to different locations in the chamber 26. The steering system may include a first flat mirror mounted on a tip-tilt actuator which may move the first mirror independently in two dimensions, and a second flat mirror mounted on a tip-tilt actuator which may move the second mirror independently in two dimensions. With this arrangement, the steering system may controllably move the focal spot in directions substantially orthogonal to the direction of beam propagation (beam axis).

As further shown in FIG. 1, the EUV light source 20 may also include a source material delivery system 90 including a droplet source 92, e.g., delivering source material, such as tin droplets, into the interior of chamber 26 to the irradiation region or primary focus 28, where the droplets will interact with light pulses from the system 22, ultimately to produce plasma and generate an EUV emission to expose the substrate 52 such as a resist coated wafer in the exposure device 50. More details regarding various droplet dispenser configurations may be found for example in U.S. Pat. No. 7,872,245, issued on Jan. 18, 2011, titled “Systems and Methods for Target Material Delivery in a Laser Produced Plasma EUV Light Source”, U.S. Pat. No. 7,405,416, issued on Jul. 29, 2008, titled “Method and Apparatus For EUV Plasma Source Target Delivery”, and U.S. Pat. No. 7,372,056, issued on May 13, 2008, titled “LPP EUV Plasma Source Material Target Delivery System”, the contents of each of which are hereby incorporated by reference in their entireties.

The source material for producing an EUV light output for substrate exposure may include, but is not necessarily limited to, a material that includes tin, lithium, xenon, or combinations thereof. The EUV emitting element, e.g., tin, lithium, xenon, etc., may be in the form of liquid droplets and/or solid particles contained within liquid droplets. For example, the element tin may be used as pure tin, as a tin compound, e.g., SnBr₄, SnBr₂, SnH₄, as a tin alloy, e.g., tin-gallium alloys, tin-indium alloys, tin-indium-gallium alloys, or a combination thereof. Depending on the material used, the source material may be presented to the irradiation region at various temperatures including room temperature or near room temperature (e.g., tin alloys, SnBr₄), at an elevated temperature, (e.g., pure tin) or at temperatures below room temperature, (e.g., SnH₄), and in some cases, can be relatively volatile, e.g., SnBr₄.

Continuing with reference to FIG. 1, the apparatus 10 may also include an EUV controller 60, which may also include a drive laser control system 65 for controlling devices in the system 22 to thereby generate light pulses for delivery into the chamber 26, and/or for controlling movement of optics in the system 22. The apparatus may also include a droplet position detection system which may include one or more droplet imagers 70 that provide an output indicative of the position of one or more droplets, e.g., relative to the irradiation region 28. The imager(s) 70 may provide this output to a droplet position detection feedback system 62, which can, e.g., compute a droplet position and trajectory, from which a droplet error can be computed, e.g., on a droplet-by-droplet basis, or on average. The droplet error may then be provided as an input to the controller 60, which can, for example, provide a position, direction and/or timing correction signal to the system 22 to control laser trigger timing and/or to control movement of optics in the system 22, e.g., to change the location and/or focal power of the light pulses being delivered to the irradiation region 28 in the chamber 26. Also, for the EUV light source 20, the source material delivery system 90 may have a control system operable in response to a signal (which in some implementations may include the droplet error described above, or some quantity derived therefrom) from the controller 60, to e.g., modify the release point, initial droplet stream direction, droplet release timing and/or droplet modulation to correct for errors in the droplets arriving at the desired irradiation region 28.

Continuing with FIG. 1, the apparatus may also include an optic 30 such as a near-normal incidence collector mirror having a reflective surface in the form of a prolate spheroid (i.e., an ellipse rotated about its major axis) having, e.g., a graded multi-layer coating with alternating layers of molybdenum and silicon, and in some cases, one or more high temperature diffusion barrier layers, smoothing layers, capping layers and/or etch stop layers. FIG. 1 shows that the optic 30 may be formed with an aperture to allow the light pulses generated by the system 22 to pass through and reach the irradiation region 28. As shown, the optic 30 may be, e.g., a prolate spheroid mirror that has a first focus within or near the irradiation region 28 and a second focus at a so-called intermediate region 40, where the EUV light may be output from the EUV light source 20 and input to an exposure device 50 utilizing EUV light, e.g., an integrated circuit lithography tool. It is to be appreciated that other optics may be used in place of the prolate spheroid mirror for collecting and directing light to an intermediate location for subsequent delivery to a device utilizing EUV light.

A buffer gas such as hydrogen, helium, argon, or combinations thereof, may be introduced into, replenished and/or removed from the chamber 26. The buffer gas may be present in the chamber 26 during plasma discharge and may act to slow plasma created ions to reduce optic degradation and/or increase plasma efficiency. Alternatively, a magnetic field and/or electric field (not shown) may be used alone, or in combination with a buffer gas, to reduce fast ion damage.

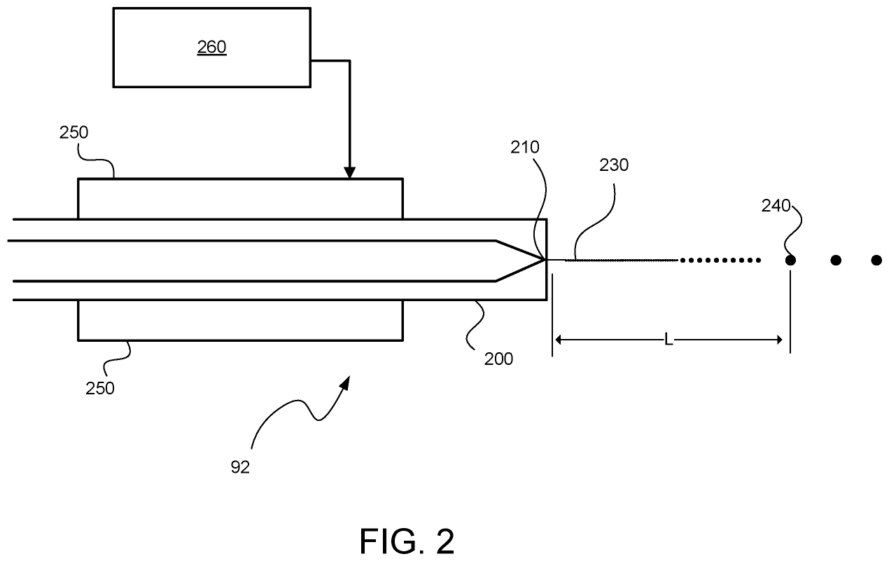

FIG. 2 illustrates the components of a simplified droplet source 92 in schematic format. As shown there, the droplet source 92 may include a capillary 200 holding a fluid, e.g., molten tin, under pressure. The capillary 200 may be made of a material such as a glass. Also shown, the capillary 200 may be formed with a nozzle with an end or orifice 210 allowing the pressurized fluid to flow through the nozzle end 210 establishing a continuous stream 230 which subsequently breaks into a stream of droplets 240. The droplet source 92 shown further includes a sub-system producing a disturbance in the fluid having an electro-actuatable element 250 that is operably coupled with the fluid and a signal generator 260 driving the electro-electro-actuatable element 250. The electro-actuatable element 250 may be any device for producing a motive force under the control of an electric signal such as a piezoelectric element.

The electro-actuatable element 250 produces a disturbance in the fluid which generates droplets having differing initial velocities causing at least some adjacent droplet pairs to coalesce together prior to reaching the irradiation region. The ratio of initial droplets to coalesced droplets may be two, three or more and in some cases tens or more. This is but one system for generating droplets. It will be apparent that other systems may be used such as, for example, systems that create an individual droplet at the nozzle orifice, e.g., for a “droplet on demand” mode in which the gas pressure is sufficient only for the formation of a droplet of target material at the nozzle orifice but is insufficient for the formation of a jet. See U.S. Pat. No. 7,449,703, titled “Method and Apparatus for EUV Plasma Source Target Delivery Target Material Handling”, issued Nov. 11, 2008, the entire disclosure of which is hereby incorporated by reference.

When the target material first exits the nozzle end 210, the target material is in the form of a velocity-perturbed steady stream 230. The stream breaks up into a series of microdroplets having varying velocities. The microdroplets coalesce into droplets of an intermediate size, referred to as subcoalesced droplets, having varying velocities with respect to one another. The subcoalesced droplets coalesce into droplets 240 having the desired final size. The number of coalescence steps can vary. The distance from the nozzle to the point at which the droplets reach their final coalesced state is the coalescence distance L.

The above description is in terms of specific types of droplet generators for the purpose of a concrete example to simplify the description only. It will be apparent that there are other arrangements for provision of a target material such as tin to the nozzle and other means of modulation that can be used and to which the teachings herein may be advantageously applied.

As mentioned, meeting the future demand for high EUV power at high repetition rates will require higher speed droplets with larger spacing between droplets. Gas acceleration of the droplets generated by a droplet generator has been considered as a way to increase droplet velocities without having to increase the driving gas pressure. The gas must be introduced into the droplet accelerator, however, in a way that does not at the same time introduce unacceptable instabilities into the droplet stream.

As mentioned, one of the chief challenges in generating droplets at higher pressures is the detrimental effect these higher pressures can have on droplet coalescence. For example, the source may require droplets of 30 microns or so in diameter traveling at a frequency of 50 kHz. Droplets coming out of the droplet generator nozzle, however, are smaller and more frequent. They are also produced with slightly varying velocities. As they travel towards the primary focus in the source they merge into larger droplets as faster droplets catch up with the slower ones. As a result, final 50 kHz, 30-micron droplets are created. This merging process, however, takes some time, so that complete coalescence of droplets happens some distance away from the nozzle. This distance is referred to as a coalescence length and identified as coalescence distance L in FIG. 2. This coalescence length will increase at high pressures, making source operation difficult as uncoalesced droplets will travel longer distances in the source and be affected by the source internal flows.

Additionally, using high pressure to produce fast droplets presents a number of problems beyond coalescent length, such as materials performance and stability at higher pressures, safety, regulatory requirements, etc.

Also, formation of SnOx particles in the nozzle is currently a problem as it leads to startup failures of the droplet generator. This may require replacement of the droplet generator with associated source downtime and cost.

Tin droplets striking inside surfaces of the EUV source in undesired locations thus leading to tin deposition or tin writing during pressurization of the droplet generator is also a problem as it can create contamination on the collector, which will lead to reduced source power output and even necessitate premature replacement of the collector.

One technical consideration in designing a gas accelerator is the location of the introduction of accelerating gas (i.e., gas for accelerating) relative to the nozzle and coalescence regions or regimes. For example, it is possible to introduce accelerating gas so that it accelerates only the full coalesced droplets. For some implementations this may have an advantage that the gas flow will not introduce perturbations in the flow of the smaller and lighter subcoalesced droplets. Such an arrangement, however, requires large amounts of gas to achieve acceleration of the larger and heavier coalescent droplets. Also, the requirement of droplets to be fully coalescent might limit its application to relatively low initial droplet generator pressure.

To avoid these restrictions, according to an aspect of an embodiment, the accelerating gas is introduced upstream of the nozzle, that is, so that the nozzle is positioned downstream of the location at which the accelerating gas is introduced, and so that the accelerating gas accelerates the entire droplet stream (microdroplets, subcoalesced droplets, and fully coalesced droplets).

According to an aspect of an embodiment, a drag-assisted droplet generator uses a gas accelerator assembly to create drag near the nozzle orifice. Because a fast flow of gas is introduced behind the nozzle and the gas accelerator assembly is located close to the nozzle, directional control of the droplet stream through the gas accelerator assembly is simplified. Here and elsewhere, “behind” and “upstream” when referring to the nozzle mean a position in a direction from the nozzle orifice opposite to the direction in which the target material stream exits the nozzle orifice. The cross-section of the gas tube can be reduced thus easing requirements for the amount of gas flow required to achieve the same acceleration by introducing the flow of accelerating gas some distance downstream of the nozzle. Additionally, since introducing accelerating gas using the new gas accelerator assembly promotes droplet coalescence, it is not necessary to start the droplet generator with a lower initial pressure. The initial pressure can be increased to higher values because droplet coalescence can be improved by the gas accelerator assembly.

The gas accelerator assembly thus promotes droplet coalescence by accelerating smaller droplets faster than the larger ones. This results in increased velocity of the resulting coalesced droplets. Such coalescence assistance is especially important for droplet generator operation at high pressures where droplet coalescence induced by electro-actuatable element 250 is weak. Also, in some embodiments it enables mild acceleration of the final droplets as well. Overall acceleration of about 10 m/s or more may be produced as an additional benefit of the coalescence assistance. It also promotes maintenance of a clean or reducing mini-environment near the nozzle orifice to reduce contamination related failures such as SnOx-related failures. This is accomplished by constantly refreshing the gas near the nozzle with a clean or reducing gas, e.g., H₂, used in the gas accelerator assembly. It also mitigates the problem of target material (e.g., tin) contamination in the source during pressurization by accelerating slow droplets to higher velocities.

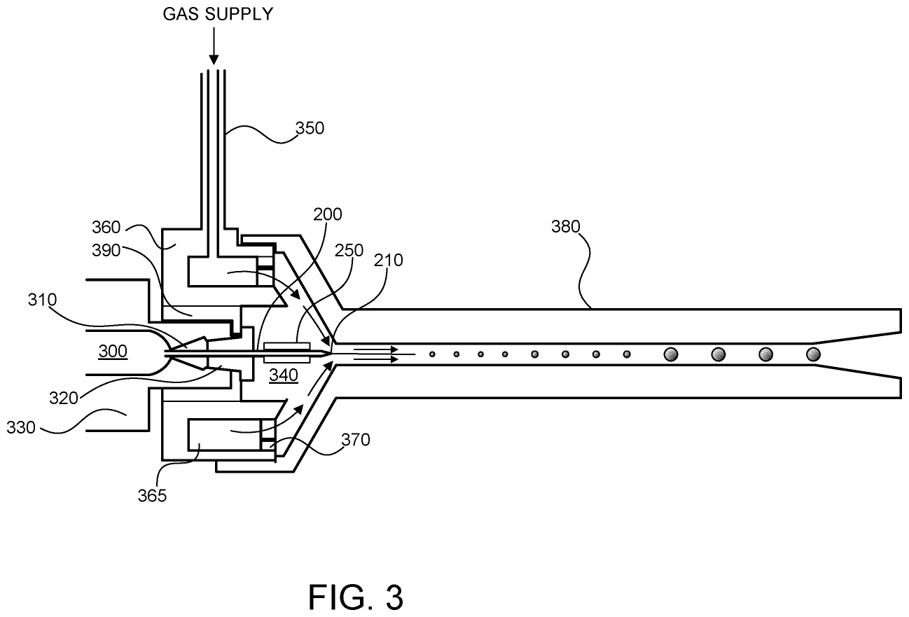

As shown in FIG. 3, the capillary 200 is in fluid communication with a cavity 300 and held in place by a ferrule 310 and a nozzle nut 320 in a nozzle body 330. The capillary 200 protrudes into a plenum 340. The gas is introduced into the plenum 340 from a gas supply through a gas supply tube 350 and an intake manifold 360 with intake manifold cavity 365. The gas from the inlet manifold 360 reaches the plenum 340 through a diffuser 370. The gas flows past the nozzle orifice of the capillary 200 and into a gas tube 380. The gas flowing into the plenum 340 and down the length of the gas tube 380 accelerates droplets in the gas tube 380 including the microdroplets and coalesced droplets from the capillary 200. An adapter 390 also holds the nozzle assembly in place. According to an aspect of an embodiment, the gas supply tube 350, the manifold 360, and the plenum 340 together constitute a gas supply system or gas introduction system.

The plenum 340 in some embodiments has a generally circular cross section with a diameter tapering in the direction from its interface with the inlet manifold 360 to its interface with the gas tube 380 such that the plenum 340 has a generally truncated conical (frustoconical) shape. Thus the cross sectional area of the plenum 340 gradually, i.e., smoothly decreases in this direction, that is, without sharp changes. This results in a circularly symmetric flow of gas starting upstream of and then flowing uniformly past the nozzle orifice outlet 210. The decrease in cross sectional area causes the gas to accelerate as it passes through the plenum 340.

Also shown in FIG. 3, according to an aspect of an embodiment the cross sectional area of the gas tube 380 is advantageously made round for some applications and even circular. The interior of the gas tube 380 is configured according to aspects of other embodiments so that the gas accelerates as it moves along the tube 380. It is in general, however, desired to avoid any sharp edges in the cross section and to make the surfaces aerodynamic.

In general, the rate at which gas flows past the nozzle orifice should be selected so that coalescence reliably occurs within the coalescence length. To achieve this, the gas introduction system is arranged and supplied with gas so as achieve a flow rate of about 0.1 slm to about 10 slm. Here and in the claims the term “about” is used to indicate that these range ends are expressions of values obtained within the precision of measurements and not expressions of abstract mathematical precision and that some deviation is permitted from the endpoints so long as performance is not adversely affected. Some embodiments can use flow rates even higher than 10 slm.

The gas entrains and accelerates the droplets in the gas tube 380. In other words, in this gas tube 380 the gas flows streamwise substantially parallel to the stream of droplets to entrain the microdroplets, subcoalesced droplets and coalesced droplets. “Substantially parallel” in this context means that the gas flow does not impart to the droplets any significant velocity that is transverse to streamwise.

According to one aspect of an embodiment, the acceleration of the droplets is selected to be gradual so as to avoid introducing instabilities into the droplet flow.

The gas used to accelerate the droplets should in general be a gas that has a low EUV absorption. One suitable gas is H₂. Another is argon. It will be apparent to those of ordinary skill in the art that other gases, and mixtures of gases, may be used as the gas which accelerates the droplets.

The material used to make the interior surfaces of the gas tube 380 are advantageously selected to be resistant to corrosion from the source material, in this example, tin. Suitable materials include refractory metals such as molybdenum, tungsten, tantalum, rhenium, and their alloys. The surfaces may also be provided with coating such as a ceramic material including BN, TiN, SiC, and CrN. If such coating is used, the underlying material of the droplet accelerator can be a more conventional alloy such as stainless steel or a similar material.

According to another aspect of embodiment, the gas used to accelerate the droplets is thermalized before being introduced into the gas tube 380.

The gas tube 380 may have a constant diameter along its length, a decreasing diameter along its length, or an increasing diameter along its length. In the case of a constant diameter tube, the gas velocity inside the tube actually increases as the gas flows from the inlet towards the outlet of the tube. This is because the gas pressure becomes smaller as the gas moves down the length of the tube, yet the mass flow rate remains constant.

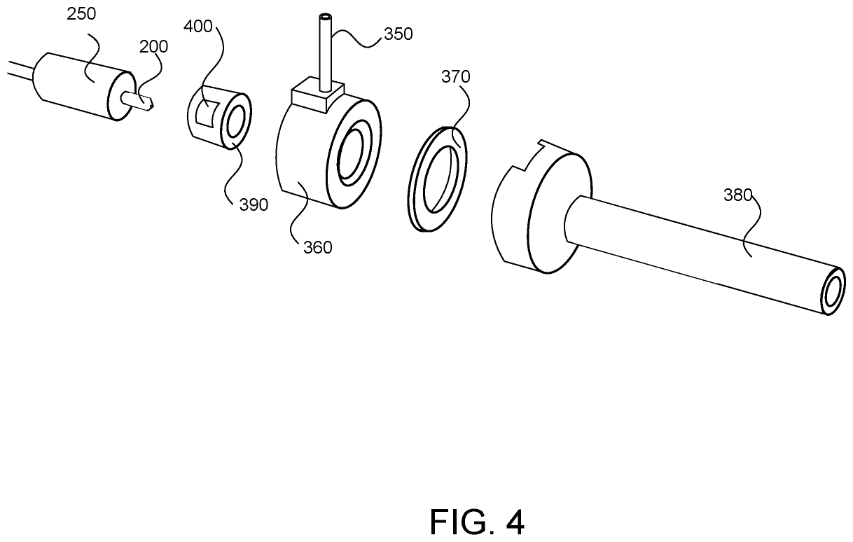

FIG. 4 is exploded view of the gas supply system of FIG. 3. As shown, the gas tube 380 fits over the manifold 360 with the diffuser 370 mounted in between. The adapter 390 is interposed between the manifold 360 and the capillary 200 with electro-actuatable element 250 being received in the adapter 390 and then that combined assembly being received in the manifold 360. The adapter 390 can be made of a resilient material. Also shown is an element 400 which is an actuator. The actuator 400 can be used make small adjustments to the angle of the capillary 200 with respect to the gas tube 380 for purposes of alignment of the stream of droplets with the interior of the gas tube 380. Some embodiments can use more than one adapters 390 to align the stream of droplets in different directions.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance. The breadth and scope of the present invention should not be limited by any of the above-described exemplary embodiments but should be defined only in accordance with the following claims and their equivalents.

The embodiments can be further described using the following clauses:
1. A droplet generator for generating a stream of droplets of extreme ultraviolet (EUV) source material, the droplet generator comprising:
a nozzle body having a nozzle orifice adapted to emit the stream of droplets of EUV source material in a streamwise direction;
a gas introduction assembly arranged to introduce a gas upstream of the nozzle orifice to flow past the nozzle orifice in the streamwise direction; and
a gas tube extending in the streamwise direction away from the nozzle orifice, the gas tube extending parallel to and substantially surrounding at least a portion of a stream path for the stream of droplets of EUV source material, the gas tube configured to cause gas in the gas tube to flow in the streamwise direction.
2. The droplet generator as in clause 1 wherein the gas introduction assembly comprises a gas inlet tube, a gas manifold in fluid communication with the gas inlet tube, and a gas plenum in fluid communication with the gas manifold, the gas plenum substantially surrounding the nozzle orifice and a portion of the nozzle body adjacent the nozzle orifice.
3. The droplet generator as in clause 2 wherein the gas plenum has a generally circular cross section with a diameter tapering in a gas flow direction from an interface with the gas manifold to an interface with the gas tube such that the plenum has a generally frustoconical shape.
4. The droplet generator as in clause 2 wherein a cross sectional area of the gas plenum gradually decreases in a gas flow direction from an interface with the gas manifold to an interface with the gas tube.
5. The droplet generator as in clause 2 wherein the gas plenum is configured to cause a circularly symmetric flow of gas starting upstream of and then flowing uniformly past the nozzle orifice.
6. The droplet generator as in clause 2 wherein the gas plenum is configured to accelerate a flow of gas starting upstream of and then flowing uniformly past the nozzle orifice.
7. The droplet generator as in clause 2 wherein the gas introduction assembly includes a diffuser positioned between the gas manifold and the gas plenum.
8. The droplet generator as in clause 1 wherein the stream of droplets EUV source material includes coalesced droplets formed within a coalescence length and wherein the gas tube extending parallel to and substantially surrounding at least a portion of the stream of liquid EUV source material extends at least the coalescence length.
9. The droplet generator as in clause 1 wherein at least a portion of the gas tube extending parallel to the stream of droplets EUV source material has a circular cross section.
10. The droplet generator as in clause 1 further comprising an adapter mechanically coupled to the nozzle body and an actuator mechanically coupled to the adapter, wherein the adapter and actuator are operable to adjust an angular position of the nozzle orifice.
11. The droplet generator as in clause 1 further comprising a gas source in fluid communication with the gas introduction assembly wherein the gas has a low EUV absorption.
12. The droplet generator as in clause 11 wherein the gas comprises hydrogen.
13. The droplet generator as in clause 11 wherein a flow rate of the gas at the nozzle orifice is in a range of about 0.1 slm to about 10 slm.
14. The droplet generator as in clause 1 wherein the gas tube comprises a refractory metal.
15. The droplet generator as in clause 14 wherein the gas tube comprises molybdenum, tungsten, tantalum, rhenium, or an alloy of molybdenum, tungsten, tantalum, or rhenium.
16. The droplet generator as in clause 1 wherein an internal surface of the gas tube comprises a boron nitride coating.
17. A method of accelerating droplets of extreme ultraviolet (EUV) source material, the method comprising:
providing a nozzle orifice adapted to emit a stream of liquid EUV source material in a streamwise direction from a front of the nozzle orifice;
providing a gas supply structure;
introducing a flow of gas around the nozzle orifice; and
emitting a stream of liquid EUV source material from the nozzle orifice, the flow of gas being introduced from a position behind the nozzle orifice with respect to the stream and flowing past the nozzle orifice in the streamwise direction.
18. The method as in clause 17 wherein the gas supply structure comprises a gas inlet tube, a gas manifold in fluid communication with the gas inlet tube, and a gas plenum in fluid communication with the gas manifold, the gas plenum substantially surrounding the nozzle orifice.
19. The method as in clause 18 wherein the gas supply structure includes a diffuser positioned between the gas manifold and the gas plenum.
20. The method as in clause 17 wherein the stream of liquid EUV source material breaks up into a stream of droplets that coalesce into coalesced droplets within a coalescence length and further comprising providing a gas tube extending parallel to and substantially surrounding at least a portion of the stream of liquid EUV source material and extending at least the coalescence length.
21. The method as in clause 20 wherein at least a portion of the gas tube extending parallel to the stream has a circular cross section.
22. The method as in clause 17 wherein the nozzle is part of a nozzle body and further comprising providing an adapter mechanically coupled to the nozzle body and an actuator mechanically coupled to the adapter, wherein the adapter and actuator are operable to adjust an angular position of the nozzle orifice.
23. The method as in clause 17 wherein the gas has a low EUV absorption.
24. The method as in clause 23 wherein the gas comprises hydrogen.
25. The method as in clause 17 wherein a flow rate of the gas at the nozzle orifice is in a range of about 0.1 slm to about 10 slm.
26. The method as in clause 20 wherein the gas tube comprises a refractory metal.
27. The method as in clause 20 wherein the gas tube comprises molybdenum, tungsten, tantalum, rhenium, or an alloy of molybdenum, tungsten, tantalum, or rhenium.
28. The method as in clause 20 wherein an internal surface of the gas tube comprises a boron nitride coating.
29. A droplet generator for generating a stream of droplets of extreme ultraviolet (EUV) source material, the droplet generator comprising:
a nozzle adapted to emit liquid EUV source material from a nozzle orifice;
at least one inlet adapted to be connected to a source of a gas; and
a first structure in fluid communication with the inlet and defining a gas plenum surrounding the nozzle orifice and extending ahead of and behind the nozzle orifice.
30. The droplet generator as in clause 29 further comprising a gas tube extending in the streamwise direction away from the nozzle orifice, the gas tube extending parallel to and substantially surrounding at least a portion of a stream path for the EUV source material, the gas tube being configured to cause gas in the gas tube to flow in the streamwise direction.
31. The droplet generator as in clause 30 wherein the gas plenum has a generally circular cross section with a diameter tapering in a gas flow direction towards an interface with the gas tube such that the plenum has a generally frustoconical shape.
32. The droplet generator as in clause 30 wherein a cross sectional area of the gas plenum gradually decreases in a gas flow direction towards an interface with the gas tube.
33. The droplet generator as in clause 29 wherein the gas plenum is configured to cause a circularly symmetric flow of gas starting upstream of and then flowing uniformly past the nozzle orifice.
34. The droplet generator as in clause 29 wherein the gas plenum is configured to accelerate a flow of gas starting upstream of and then flowing uniformly past the nozzle orifice.
35. A method of accelerating droplets of extreme ultraviolet (EUV) source material, the method comprising:
emitting a stream of liquid EUV source material from a nozzle orifice of a droplet generator; and
causing gas to flow past the nozzle orifice and parallel to the stream of liquid EUV source material to entrain and accelerate droplets of EUV source material in the stream of liquid EUV source material.

These and other implementations are within the scope of the claims.

1. A droplet generator for generating a stream of droplets of extreme ultraviolet (EUV) source material, the droplet generator comprising:
a nozzle body having a nozzle orifice adapted to emit the stream of droplets of EUV source material in a streamwise direction;
a gas introduction assembly arranged to introduce a gas upstream of the nozzle orifice to flow past the nozzle orifice in the streamwise direction; and
a gas tube extending in the streamwise direction away from the nozzle orifice, the gas tube extending parallel to and substantially surrounding at least a portion of a stream path for the stream of droplets of EUV source material, the gas tube configured to cause gas in the gas tube to flow in the streamwise direction.

2. The droplet generator as in claim 1 wherein the gas introduction assembly comprises a gas inlet tube, a gas manifold in fluid communication with the gas inlet tube, and a gas plenum in fluid communication with the gas manifold, the gas plenum substantially surrounding the nozzle orifice and a portion of the nozzle body adjacent the nozzle orifice.

3. The droplet generator as in claim 2 wherein the gas plenum has a generally circular cross section with a diameter tapering in a gas flow direction from an interface with the gas manifold to an interface with the gas tube such that the plenum has a generally frustoconical shape.

4. (canceled)

5. The droplet generator as in claim 2 wherein the gas plenum is configured to cause a circularly symmetric flow of gas starting upstream of and then flowing uniformly past the nozzle orifice.

6. (canceled)

7. The droplet generator as in claim 2 wherein the gas introduction assembly includes a diffuser positioned between the gas manifold and the gas plenum.

8. The droplet generator as in claim 1 wherein the stream of droplets EUV source material includes coalesced droplets formed within a coalescence length and wherein the gas tube extending parallel to and substantially surrounding at least a portion of the stream of liquid EUV source material extends at least the coalescence length.

9. (canceled)

10. The droplet generator as in claim 1 further comprising an adapter mechanically coupled to the nozzle body and an actuator mechanically coupled to the adapter, wherein the adapter and actuator are operable to adjust an angular position of the nozzle orifice.

11. The droplet generator as in claim 1 further comprising a gas source in fluid communication with the gas introduction assembly wherein the gas has a low EUV absorption.

12. (canceled)

13. The droplet generator as in claim 11 wherein a flow rate of the gas at the nozzle orifice is in a range of about 0.1 slm to about 10 slm.

14. The droplet generator as in claim 1 wherein the gas tube comprises a refractory metal.

15. (canceled)

16. The droplet generator as in claim 1 wherein an internal surface of the gas tube comprises a boron nitride coating.

17. A method of accelerating droplets of extreme ultraviolet (EUV) source material, the method comprising:
providing a nozzle orifice adapted to emit a stream of liquid EUV source material in a streamwise direction from a front of the nozzle orifice;
providing a gas supply structure;
introducing a flow of gas around the nozzle orifice; and
emitting a stream of liquid EUV source material from the nozzle orifice, the flow of gas being introduced from a position behind the nozzle orifice with respect to the stream and flowing past the nozzle orifice in the streamwise direction.

18. The method as in claim 17 wherein the gas supply structure comprises a gas inlet tube, a gas manifold in fluid communication with the gas inlet tube, and a gas plenum in fluid communication with the gas manifold, the gas plenum substantially surrounding the nozzle orifice.

19. The method as in claim 18 wherein the gas supply structure includes a diffuser positioned between the gas manifold and the gas plenum.

20. The method as in claim 17 wherein the stream of liquid EUV source material breaks up into a stream of droplets that coalesce into coalesced droplets within a coalescence length and further comprising providing a gas tube extending parallel to and substantially surrounding at least a portion of the stream of liquid EUV source material and extending at least the coalescence length.

21. (canceled)

22. The method as in claim 17 wherein the nozzle is part of a nozzle body and further comprising providing an adapter mechanically coupled to the nozzle body and an actuator mechanically coupled to the adapter, wherein the adapter and actuator are operable to adjust an angular position of the nozzle orifice.

23. The method as in claim 17 wherein the gas has a low EUV absorption.

24. (canceled)

25. The method as in claim 17 wherein a flow rate of the gas at the nozzle orifice is in a range of about 0.1 slm to about 10 slm.

26. The method as in claim 20 wherein the gas tube comprises a refractory metal.

27. (canceled)

28. (canceled)

29. A droplet generator for generating a stream of droplets of extreme ultraviolet (EUV) source material, the droplet generator comprising:
a nozzle adapted to emit liquid EUV source material from a nozzle orifice;
at least one inlet adapted to be connected to a source of a gas; and
a first structure in fluid communication with the inlet and defining a gas plenum surrounding the nozzle orifice and extending ahead of and behind the nozzle orifice.

30. The droplet generator as in claim 29 further comprising a gas tube extending in the streamwise direction away from the nozzle orifice, the gas tube extending parallel to and substantially surrounding at least a portion of a stream path for the EUV source material, the gas tube being configured to cause gas in the gas tube to flow in the streamwise direction.

31. The droplet generator as in claim 30 wherein the gas plenum has a generally circular cross section with a diameter tapering in a gas flow direction towards an interface with the gas tube such that the plenum has a generally frustoconical shape.

32-35. (canceled)
